(19) United States
(12) Patent Application Publication
(10) Pub. No.: US 2024/0414985 A1
(43) Pub. Date: Dec. 12, 2024

(54) DISPLAY DEVICE

(71) Applicant: Samsung Display Co., LTD., Yongin-si Gyeonggi-do (KR)

(72) Inventors: Sunho KANG, Yongin-si (KR); Deok-Young CHOI, Yongin-si (KR); Won Jang KI, Yongin-si (KR)

(21) Appl. No.: 18/443,812

(22) Filed: Feb. 16, 2024

(30) Foreign Application Priority Data
Jun. 12, 2023 (KR) 10-2023-0074706

(51) Int. Cl. H10K 59/80; H10K 59/122; H10K 59/131

(52) U.S. Cl. CPC H10K 59/874; H10K 59/122; H10K 59/131

(57) ABSTRACT

A display device includes a substrate including a display area and a non-display area, a transistor positioned in the display area, a light emitting element electrically connected to the transistor, and a common voltage transmission line positioned in the non-display area and including a depression, a transmission line, a first dam and a second dam positioned in the non-display area and spaced apart from each other and surrounding at least a portion of the display area, and a cover organic layer overlapping an edge of the recessed portion, wherein an edge of the recessed portion is positioned between the first dam and the second dam.

This application claims priority to Korean Patent Application No. 10-2023-0074706, filed on Jun. 12, 2023, and all the benefits accruing therefrom under 35 U.S.C. § 119, the content of which in its entirety is herein incorporated by reference.

### BACKGROUND

### (a) Field

The present invention relates to a display device, and more particularly, to a display configured to prevent moisture permeation.

### (b) Description of the Related Art

A display device is a device that includes a screen having a liquid crystal display LCD, a light emitting diode LED, and the like.

Such display devices are used in various electronic devices such as mobile phones, navigation devices, digital cameras, electronic books, portable game consoles, and terminals.

The light emitting display, which is a self-emissive display device, does not require a separate light source, so it can be driven with low voltage, can be configured as lightweight and thin, and has high-quality characteristics such as a wide viewing angle, high contrast, and fast response speed, and is attracting attention as a display device.

### SUMMARY

Embodiments include a display device having an enhanced function for preventing permeation of moisture or oxygen from the outside.

A display device according to an embodiment includes a substrate including a display area and a non-display area, a transistor positioned in the display area, a light emitting element electrically connected to the transistor, and a common voltage transmission line positioned in the non-display area and including a depression, a transfer line, a first dam and a second dam positioned in the non-display area, surrounded by at least a portion of the display area and spaced apart from each other, and a cover organic layer overlapping an edge of the recessed portion, wherein an edge of the recessed portion is positioned between the first dam and the second dam.

In an embodiment, the common voltage transmitting wire may include a first area having a first width and a second area having a second width, wherein the first width may be greater than the second width.

In an embodiment, the shape of the second region may be recessed more than the first region.

In an embodiment, the common voltage transmission line includes a first edge and a second edge, wherein the first edge is positioned adjacent to the first dam, the second edge is positioned adjacent to the second dam, and at least a part of the second edge may overlap the second dam.

In an embodiment, the second edge may include a portion protruding toward the first edge, wherein the protruding portion may overlap the cover organic layer.

In an embodiment, the display area includes a first semiconductor layer on the substrate, a first gate conductive layer on the first semiconductor layer, a second gate conductive layer on the first gate conductive layer, a second semiconductor layer positioned on the second gate conductive layer, a third gate conductive layer positioned on the second semiconductor layer, a first data conductive layer positioned on the third gate conductive layer, and a layer positioned on the first data conductive layer, wherein the layer positioned on the first data conductive layer may include a second data conductive layer positioned thereon, and a first electrode positioned on the second data conductive layer.

In an embodiment, the common voltage transmission line may include at least one of a first layer positioned on the same layer as the first data conductive layer and a second layer positioned on the same layer as the second data conductive layer.

In an embodiment, the display device may further include an alignment key overlapping at least a portion of the recessed portion on a plane.

In an embodiment, the alignment key may be positioned on the same layer as the third gate conductive layer.

In an embodiment, the display device may include a first gate insulation layer on the first semiconductor layer, a second gate insulation layer on the first gate conductive layer, a first interlayer insulating layer on the second gate conductive layer, a third gate insulation layer on the second semiconductor layer, a second interlayer insulating layer on the third gate conductive layer, a first organic layer on the first data conductive layer, and a second data conductive layer on the second semiconductor layer, wherein a second organic layer and a third organic layer may be positioned on the first electrode and may include a pixel defining layer and a spacer positioned on the first electrode.

In an embodiment, the cover organic layer may include the same material as at least one of the second organic layer and the third organic layer.

In an embodiment, the cover organic layer may be connected to the second dam.

In an embodiment, the first dam and the cover organic layer may be spaced apart from each other.

In an embodiment, the cover organic layer may have a planar shape protruding toward the first dam.

A display device according to an embodiment includes a substrate including a display area and a non-display area, a transistor positioned in the display area, a light emitting element electrically connected to the transistor, a common voltage transfer line positioned in the non-display area, a first dam and a second dam positioned in a display area, surrounding at least a portion of the display area, and spaced apart from each other, a cover organic layer protruding from a portion of the second dam and spaced apart from the first dam, wherein the cover organic layer covers at least a portion of an edge of the common voltage transmission line.

In an embodiment, the common voltage transmission line may include a first edge adjacent to the first dam and a second edge adjacent to the second dam, wherein the second edge may include a portion protruding toward the first dam.

In an embodiment, the cover organic layer may cover a protruding portion of the second edge.

In an embodiment, at least a portion of the second edge may overlap the second dam.

In an embodiment, the common voltage transmission line may include a first area having a first width and a second area having a second width, wherein the first width may be greater than the second width.

In an embodiment, the display device may further include an alignment key overlapping at least a portion of the second dam.

According to an embodiment, penetration of moisture or oxygen from the outside into the display device may be blocked by blocking the connection between adjacent organic layers in the non-display area.

In an embodiment, a display device with improved reliability may be provided through moisture permeation prevention.

### BRIEF DESCRIPTION OF THE DRAWINGS

The above and other advantages and features of the invention will become more apparent by describing in further detail embodiments thereof with reference to the accompanying drawings, in which:

FIG. 1 is an exploded perspective view of a display device, according to an embodiment.

FIG. 2 is a schematic top plan view of a display panel, according to an embodiment.

FIG. 3 is a circuit diagram of one pixel of the display panel, according to an embodiment.

FIG. 4 is a schematic cross-sectional view of a display panel, according to an embodiment.

FIG. 5 is an enlarged top plan view of region A of FIG. 2, according to an embodiment.

FIG. 6 is a cross-sectional view taken along the line A-A′ of FIG. 5, according to an embodiment.

FIG. 7 is a cross-sectional view taken along the line B-B′ of FIG. 5, according to an embodiment.

### DETAILED DESCRIPTION

Hereinafter, with reference to the accompanying drawings, various embodiments will be described in detail so that a person of an ordinary skill in the art can easily carry out the present invention.

This invention may be embodied in many different forms and is not limited to the embodiments set forth herein.

In order to clearly describe the present invention, parts irrelevant to the description are omitted, and the same reference numerals are assigned to the same or similar constituent elements throughout the specification. Within the Figures and the text of the disclosure, a reference number indicating a singular form of an element may also be used to reference a plurality of the singular element.

In addition, since the size and thickness of each component shown in the drawings are arbitrarily shown for convenience of explanation, the present invention is not necessarily limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be related to another element such as being “above” or “on” another part, this includes not only the case where the part is “directly on” the other part, but also the case where another part exists in the middle thereof.

Conversely, when a part is said to be related to another element such as being “directly on” another part, it means that there is no other part in between.

In addition, being “above” or “on” a reference part means being positioned above or below the reference part and does not necessarily mean being positioned “above” or “on” it in the opposite direction of gravity.

In addition, throughout the specification, when a certain component is said to “include,” it means that it may further include other components without excluding other components unless otherwise stated.

Also, throughout the specification, when reference is made to a “planar image,” it means when the target part is viewed from above, and when reference is made to a “cross-sectional image,” it means when the cross-section of the target part cut vertically is viewed from the side.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise,” and variations such as “comprises” or “comprising,” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

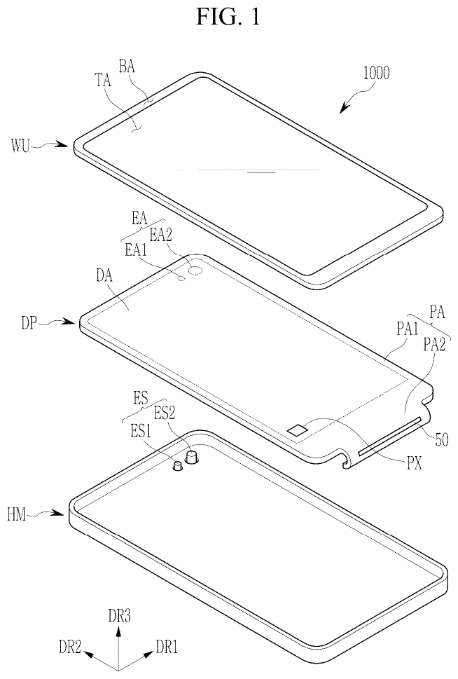

Hereinafter, a schematic structure of a display device will be described with reference to FIG. 1.

FIG. 1 is an exploded perspective view of a display device, according to an embodiment.

Referring to FIG. 1, the display device 1000 according to an embodiment is a device for displaying videos or still images, and may be used as a display screen for various products such as mobile phones, smart phones, tablet personal computers, mobile communication terminals, electronic notebooks, e-books, portable multimedia players PMP, navigation, ultramobile PC UMPC, as well as televisions, notebooks, monitors, billboards, and the Internet of Things IoT.

Furthermore, the display device 1000 according to an embodiment may be used in wearable devices such as smart watches, watch phones, glasses-type displays, and head-mounted displays HMD.

Also, the display device 1000 according to an embodiment may be used as a car's instrument panel, a center information display CID placed on the car's center fascia or dashboard, a room mirror display replacing the car's side mirror, and a display placed on the back of the front seat for rear seat entertainment in a car.

In an embodiment, FIG. 1 illustrates, for convenience of explanation, that the display device 1000 is used as a smart phone.

In an embodiment, the display device 1000 may display images towards the third direction DR3 on the display surface which is parallel to both the first direction DR1 and the second direction DR2.

In an embodiment, the display screen where the video is shown may correspond to the front surface of the display device 1000, and may correspond to the front of the cover window WU.

In an embodiment, the video may include not only dynamic images but also may include still images.

In an embodiment, the front or upper surface and rear surface or lower surface of each member are defined based on the direction in which the image is displayed.

In an embodiment, the front and back faces oppose each other in the third direction DR3, and the normal directions of each of the front and back face may be parallel to the third direction DR3.

In an embodiment, the deviation distance from the third direction DR3 between the front and back faces may correspond to the thickness of the display panel in the third direction DR3.

In an embodiment, the display device 1000 according to an embodiment may detect the input of a user authorized from the outside.

In an embodiment, the user's input may include various types of external inputs, such as a part of the user's body, light, heat, or pressure.

In an embodiment, user input may be provided in various forms.

Also, in an embodiment, the display device 1000 may detect a user's input applied to the side or back of the display device 1000 depending on the structure of the display device 1000.

In an embodiment, the display device 1000 may include a cover window WU, a housing HM, a display panel DP, and an optical device ES.

In an embodiment, the cover window WU and housing HM may be combined to form the appearance of the display device 1000.

In an embodiment, the cover window WU may include an insulating panel.

For example, in an embodiment, the cover window WU may be made of glass, plastic, or a combination thereof.

In an embodiment, the front of the cover window WU may define the front of the display device 1000.

In an embodiment, the transmission region TA may be an optically transparent region.

For example, in an embodiment, the transmission region TA may be an area with a visible light transmittance rate of more than about 90%.

In an embodiment, the blocking region BA may define the shape of the transmission region TA.

In an embodiment, the blocking region BA is located adjacent to the transmission region TA and may surround the transmission region TA.

In an embodiment, the blocking region BA may be a region with a relatively lower light transmittance compared to the transmission region TA.

In an embodiment, the blocking region BA may include an opaque material that blocks light.

In an embodiment, the blocking region BA may have a certain color.

In an embodiment, the blocking region BA may be defined by a bezel layer provided separately from the transparent substrate that defines the transmission region TA, or it may be defined by an ink layer that is inserted or dyed into the transparent substrate.

In an embodiment, the display panel DP may include a front face containing a display area DA and a non-display area PA.

In an embodiment, the display area DA may be an area where pixels operate and emit light according to electrical signals.

In an embodiment, the non-display area PA of the display panel DP may include a driving part 50.

In an embodiment, the display area DA is an area where an image is displayed, including pixels, and at the same time, a touch sensor may be positioned in the upper direction of the third direction DR3 of the pixels, which may be an area where external input is detected.

In an embodiment, the transmission region TA of the cover window WU may overlap at least partially the display area DA of the display panel DP.

For example, in an embodiment, the transmission region TA may overlap the front of the display area DA, or it may overlap at least part of the display area DA.

Accordingly, in an embodiment, the user may view an image through the transmission region TA or provide an external input based on the image.

However, the present invention is not limited thereto.

For example, in an embodiment, within the display area DA, a region where an image is displayed and a region where an external input is sensed may be separated from each other.

In an embodiment, the non-display area PA of the display panel DP may overlap at least partially the blocking region BA of the cover window WU.

In an embodiment, the non-display area PA may be an area covered by the blocking region BA.

In an embodiment, the non-display area PA is located adjacent to the display area DA, and may surround the display area DA.

In an embodiment, the non-display area PA is where the image is not displayed, and it may be the place where the drive circuit or wiring for operating the display area DA may be arranged.

In an embodiment, the non-display area PA may include a first non-display area PA1 positioned outside the display area DA, and a second non-display area PA2 that includes a drive part 50, connection wiring, and a bending region.

In an embodiment, the first non-display area PA1 is positioned on three sides of the display area DA, and the second non-display area PA2 is positioned on the remaining one side of the display area DA.

In an embodiment, the display panel DP may be assembled in a flat state facing the cover window WU, with the display area DA and non-display area PA.

However, the present invention is not limited thereto.

In an embodiment, a part of the non-display area PA of the display panel DP may be bent.

In an embodiment, some of the non-display area PA is directed towards the back of the display device 1000, which may reduce the blocking region BA that is visible on the front of the display device 1000, and in FIG. 1, the second non-display area PA2 may be bent and assembled after being positioned at the back of the display area DA.

Additionally, in an embodiment, the display panel DP may include a component region EA, and specifically, it may include a first component region EA1 and a second component region EA2.

In an embodiment, the first component region EA1 and the second component region EA2 may be at least partially surrounded by the display area DA.

In an embodiment, the first component region EA1 and the second component region EA2 are depicted as being separate from each other, but they are not limited to this and may be at least partially connected.

In an embodiment, the first component region EA1 and the second component region EA2 may be areas where components using infrared light, visible light, and/or sound are positioned underneath.

In an embodiment, the display area DA is formed with a plurality of light emitting diodes and a plurality of pixel circuits that generate and transmit light emitting currents to each of the light emitting diodes.

Here, a single light emitting diode and a single pixel circuit part are referred to as a pixel PX, according to an embodiment.

In an embodiment, in the display area DA, one pixel circuit unit and one light emitting diode are formed one to one.

In an embodiment, the first component region EA1 may include a transmission part through which light and/or sound may pass and a display portion including a plurality of pixels.

In an embodiment, the transmission part is positioned between adjacent pixels and is composed of a layer through which light and/or sound may pass.

In an embodiment, the transmission part may be positioned between adjacent pixels, and depending on embodiments, a layer that does not transmit light, such as a light blocking member, may overlap the first component region EA1.

In an embodiment, the number of pixels per unit area, hereinafter referred to as resolution of the pixels, hereinafter referred to as normal pixels, included in the display area DA and the pixels included in the first component region EA1, hereinafter referred to as first component pixels, may be the same.

In an embodiment, the second component region EA2 includes an area made of a transparent layer to allow light to pass therethrough, hereinafter referred to as a light transmitting area, wherein a layer—e.g., a pixel defining layer and/or a light blocking member—may include an opening overlapping a position corresponding to the second component region EA2 so as not to block light.

In an embodiment, the number of pixels per unit area of the pixels, hereinafter referred to as second component pixels, included in the second component region EA2 may be smaller than the number of pixels per unit area of normal pixels included in the display area DA.

As a result, in an embodiment, the resolution of the second component pixels may be lower than that of normal pixels.

In an embodiment, the drive unit 50 may be mounted on the second non-display area PA2 and may be mounted on the bending unit or positioned on either side of the bending unit.

In an embodiment, the drive unit 50 may be provided in the form of a chip.

In an embodiment, the drive unit 50 is electrically connected to the display area DA and may transmit an electrical signal to the display area DA.

For example, in an embodiment, the drive unit 50 may provide data signals to the pixels PX that are located in the display area DA.

Alternatively, in an embodiment, the drive unit 50 may include a touch drive circuit, and may be electrically connected to a touch sensor positioned in the display area DA.

In an embodiment, the drive unit 50 may be designed to include various circuits other than the aforementioned circuits, or to provide various electrical signals to the display area DA.

In an embodiment, the display device 1000 may have a pad unit positioned at the end of the second non-display area PA2, and may be electrically connected to the flexible printed circuit board FPCB, which includes a drive chip, by the pad unit.

In an embodiment, the drive chip positioned on the printed circuit board here may include various drive circuits for driving the display device 1000 and connectors for a power supply.

According to an embodiment, a rigid printed circuit board PCB may be used instead of a flexible printed circuit board.

In an embodiment, an optical device ES may be placed under the display panel DP.

In an embodiment, the optical device ES may include a first optical device ES1 that overlaps the first component region EA1 and a second optical device ES2 that overlaps the second component region EA2.

In an embodiment, the first optical device ES1 may be an electronic component that uses light and/or sound.

For example, in an embodiment, the first optical device ES1 may be a sensor that receives and uses light such as an infrared sensor, a sensor that outputs and detects light or sound to measure a distance and/or recognizes a fingerprint, and/or a small lamp that outputs light, and/or it may be a speaker or the like that outputs sound.

In an embodiment, an electronic element using light, light of various wavelength bands such as visible light, infrared light, and ultraviolet light may be used.

In an embodiment, the second optical device ES2 may be at least one of a camera, an infrared camera IR camera, a dot projector, an infrared illuminator IR illuminator, and a time-of-flight sensor ToF sensor.

In an embodiment, the housing HM may be combined with the cover window WU.

In an embodiment, the cover window WU may be placed in front of the housing HM.

In an embodiment, the housing HM may be combined with the cover window WU to provide a certain accommodation space.

In an embodiment, the display panel DP and optical device ES may be accommodated in a certain accommodation space provided between the housing HM and the cover window WU.

In an embodiment, the housing HM may contain materials with relatively high rigidity.

For example, in an embodiment, the housing HM may include a plurality of frames and/or plates made of glass, plastic, metal, or a combination thereof.

In an embodiment, the housing HM may stably protect components of the display device 1000 accommodated within the inner (accommodation) space from external impact.

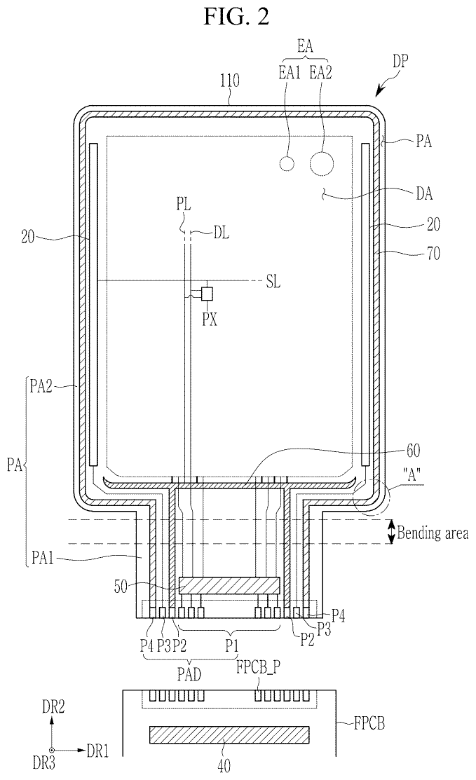

Hereinafter, the structure of the display panel will be described with reference to FIG. 2, according to an embodiment.

FIG. 2 is a plan view of a display panel, according to an embodiment.

In an embodiment and referring to FIG. 2, the display panel DP may include a display area DA, a component region EA, and a non-display area PA, wherein the non-display area PA may be defined along the border of the display area DA.

In an embodiment, the non-display area PA may include a first non-display area PA1 that includes a data driving part 50, connection wiring, and a bending region, and a second non-display area PA2 positioned outside the display area DA.

In an embodiment, the display panel DP includes a plurality of pixels PX.

In an embodiment, a plurality of pixels PX may be placed within the display area DA.

In an embodiment, each of the pixels PX includes a light emitting element and a pixel circuit unit connected thereto.

In an embodiment, each pixel PX emits, for example, red, green, blue, or white light, and may include, for example, an organic light emitting diode.

In an embodiment, the display panel DP may include a plurality of signal lines and a pad unit.

In an embodiment, a plurality of signal lines may include a scan line SL extending in a first direction DR1, a data line DL extending in a second direction DR2, and a drive voltage line PL, etc.

In an embodiment, the scan drive unit 20 is positioned on both sides of the display area DA, generating and transmitting scan signals to each pixel PX through the scan line SL.

In an embodiment, the pixels PX may receive scan signals from the two scan drivers 20 positioned on the left and right sides together.

In an embodiment, the pad unit PAD; hereinafter also referred to as the circuit board pad unit is positioned at one end of the first non-display area PA1 of the display panel DP, and may include terminals P1, P2, P3, P4.

In an embodiment, the pad unit PAD may be electrically connected to the flexible printed circuit board FPCB, as it is not covered by the insulation layer and is exposed.

In an embodiment, the pad unit PAD may be electrically connected to the pad unit of the flexible printed circuit board FPCB.

In an embodiment, the flexible printed circuit board FPCB may transmit signals or power from the IC drive chip 40 to the pad unit PAD.

In an embodiment, the IC drive chip 40 converts a plurality of video signals transmitted from the outside into a plurality of video data signals, and delivers the converted signals to the data drive unit 50 through the terminal P1.

Also, in an embodiment, the IC drive chip 40 may receive vertical synchronization signals, horizontal synchronization signals, and clock signals to generate control signals for controlling the operation of the scan drive part 20 and the data drive part 50, and deliver control signals to each scan drive part 20 and the data drive part 50 through the terminals P3, P1.

In an embodiment, the IC drive chip 40 delivers the drive voltage to the drive voltage supply wiring 60 through the terminal P2.

Furthermore, in an embodiment, the IC drive chip 40 may deliver a common voltage to each common voltage delivery wiring 70 through the terminal P4.

In an embodiment, the data drive unit 50 is placed on the first non-display area PA1, and generates data voltage to be applied to each pixel PX and delivers the data voltage to each data line DL.

In an embodiment, the data drive unit 50 may be positioned on one side of the display panel DP—for example, it may be placed between the pad unit PAD and the display area DA.

In an embodiment, the data lines DL connected to the remaining pixels PX excluding the pixels PX positioned on the upper and lower sides of the component region EA along the second direction DR2 may be extended along the second direction DR2 and may have a straight-line structure.

In contrast, in an embodiment, the data line DL connected to the pixel PX positioned above and below the component region EA may extend in the second direction DR2, but in the vicinity of the component region EA, it may also include a portion that extends along the periphery of the component region EA.

In an embodiment, the drive voltage supply wiring 60 is arranged on the first non-display area PA1.

For instance, in an embodiment, the drive voltage supply wiring 60 may be placed between the data drive part 50 and the display area DA.

In an embodiment, the drive voltage supply wiring 60 provides the driving voltage to the pixels PX.

In an embodiment, the drive voltage supply wiring 60 is arranged in a first direction DR1 and may be connected to a plurality of drive voltage lines PL arranged in a second direction DR2.

In an embodiment, the common voltage transmission line 70 is arranged on the first non-display area PA1.

In an embodiment, the common voltage transmission line 70 may have a shape surrounding the substrate 110.

In an embodiment, the common voltage transmission line 70 delivers the common voltage to one electrode, for example, a cathode of the light emitting element included in the pixel PX.

In an embodiment, the first non-display area PA1 may include a bending region.

In an embodiment, the bending region may be positioned between the display area DA and the pad unit PAD.

In an embodiment, a plurality of inorganic layers may be removed in the bending region.

In an embodiment, the inorganic layer is not included in the bending region.

In an embodiment, an insulating layer made of an organic material and may be positioned in the bending region.

In an embodiment, in the bending region, an insulating layer made of an organic material may be positioned at the outermost part.

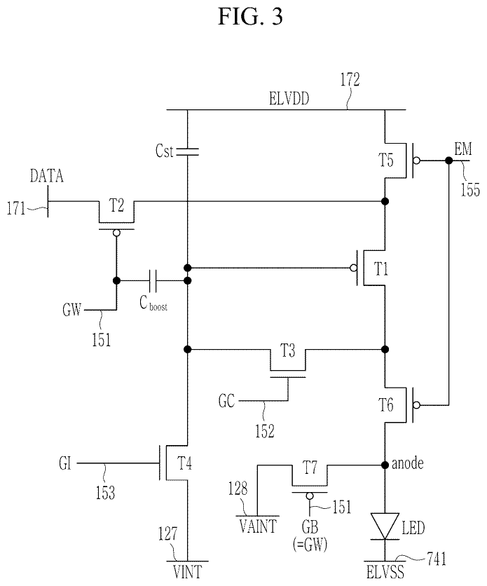

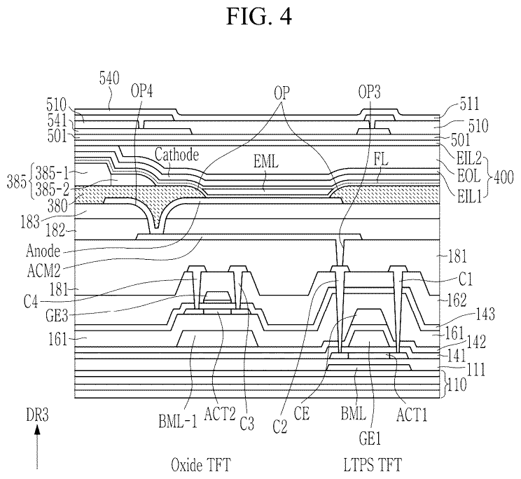

Hereinafter, one pixel positioned in the display area will be described with reference to FIG. 3 and FIG. 4, according to an embodiment.

FIG. 3 is a circuit diagram of one pixel, according to an embodiment, and FIG. 4 is a schematic cross-sectional view of a display panel, according to an embodiment.

Firstly, referring to FIG. 3, one pixel, according to an embodiment, includes a plurality of transistors T1, T2, T3, T4, T5, T6, T7 connected to several wirings 127, 128, 151, 152, 153, 155, 171, 172, 741, a storage capacitor Cₛₜ, a boost capacitor C_{boost}, and a light emitting diode LED.

Here, transistors and capacitors other than the light emitting diode LED constitute a pixel circuit unit.

In an embodiment, the boost capacitor C_{boost} may be omitted.

In an embodiment, additional capacitors or boost capacitors may be formed.

In an embodiment, a plurality of wires 127, 128, 151, 152, 153, 155, 171, 172, 741 are connected to one pixel PX.

In an embodiment, a plurality of wirings include the first initialization voltage line 127, the second initialization voltage line 128, the first scan line 151, the second scan line 152, the initialization control line 153, the light emission control line 155, the data line 171, the drive voltage line 172, and the common voltage line 741.

In an embodiment, the first scan line 151 is connected to the scan drive part not shown and transmits the first scan signal GW to the second transistor T2 and the seventh transistor T7.

In an embodiment, the second scan line 152 may be applied with a voltage of opposite polarity to the voltage applied to the first scan line 151 at the same time as the signal of the first scan line 151.

For example, in an embodiment, when a negative voltage is applied to the first scan line 151, a positive voltage may be applied to the second scan line 152.

In an embodiment, the second scan line 152 transmits the second scan signal GC to the third transistor T3.

In an embodiment, the initialization control line 153 delivers the initialization control signal GI to the fourth transistor T4.

In an embodiment, the light emitting control line 155 delivers the light emitting control signal EM to the fifth transistor T5 and the sixth transistor T6.

In an embodiment, the data line 171 is a wiring that delivers data voltage DATA generated from the data driving section not shown, thereby changing the size of the light emitting current delivered to the light emitting diode LED, which in turn changes the luminance of the light emitting diode LED.

In an embodiment, the drive voltage line 172 applies the drive voltage ELVDD.

In an embodiment, the first initialization voltage line 127 delivers the first initialization voltage VINT, and the second initialization voltage line 128 delivers the second initialization voltage VAINT.

In an embodiment, the common voltage line 741 applies the common voltage ELVSS to the cathode of the light emitting diode LED.

In an embodiment, the voltages applied to the drive voltage line 172, the first and second reset voltage lines 127, 128, and the common voltage line 741 may each be a constant voltage.

In an embodiment, the drive transistor T1 also referred to as a first transistor is a p-type transistor, and has a silicon semiconductor hereinafter referred to as a polycrystalline semiconductor or a first semiconductor as a semiconductor layer.

In an embodiment, T1 is a transistor that adjusts the size of the light emitting current output to the anode of the light emitting diode LED depending on the size of the voltage i.e., the voltage stored in the storage capacitor Cst of the gate electrode of the drive transistor T1.

In an embodiment, the brightness of the light emitting diode LED may be adjusted depending on the amount of the light emitting current being output from the anode electrode of the LED, and therefore, the luminous intensity of the LED may be adjusted according to the data voltage DATA applied to the pixel.

In an embodiment, the first electrode of the drive transistor T1 is arranged to receive the driving voltage ELVDD, and is connected to the drive voltage line 172 via the fifth transistor T5.

Also, In an embodiment, the first electrode of the drive transistor T1 is connected to the second electrode of the second transistor T2, and also receives the data voltage DATA.

In an embodiment, the second electrode of the drive transistor T1 outputs a light emitting current through the light emitting diode LED, and is connected to the anode of the light emitting diode LED via the sixth transistor T6, also referred to as the output control transistor.

In an embodiment, the second electrode of the drive transistor T1 is connected to the third transistor T3, and it transfers the data voltage DATA applied to the first electrode to the third transistor T3.

In an embodiment, the gate electrode of the drive transistor T1 is connected to one electrode of the storage capacitor Cst, hereinafter referred to as the second storage electrode.

In an embodiment, the storage capacitor Cst receives the drive voltage ELVDD from another electrode hereinafter referred to as the first maintenance electrode.

In an embodiment, the voltage of the gate electrode of the drive transistor T1 changes depending on the voltage stored in the storage capacitor Cst, and the light emitting current output by the drive transistor T1 changes accordingly.

In an embodiment, the storage capacitor Cst serves to maintain the voltage of the gate electrode of the drive transistor T1 constant during one frame.

In an embodiment, the gate electrode of the drive transistor T1 may be connected to the third transistor T3, allowing the data voltage DATA applied to the first electrode of the drive transistor T1 to be transmitted to the gate electrode of the drive transistor T1 through the third transistor T3.

In an embodiment, the gate electrode of the drive transistor T1 may be connected to the fourth transistor T4 and initialized by receiving the first initialization voltage VINT.

In an embodiment, the second transistor T2 is a p-type transistor and has a silicon semiconductor as a semiconductor layer.

In an embodiment, the second transistor T2 is a transistor that receives data voltage DATA within the pixel.

In an embodiment, the gate electrode of the second transistor T2 is connected to the first scan line 151 and one electrode of the boost capacitor C_{boost}, also referred to as the lower boost electrode.

In an embodiment, the other electrode of the boost capacitor C_{boost} is connected to the gate electrode of the drive transistor T1 and the second holding electrode of the holding capacitor Cst.

In an embodiment, the first electrode of the second transistor T2 is connected to the data line 171, and the second electrode of the second transistor T2 is connected to the first electrode of the drive transistor T1.

In an embodiment, when the second transistor T2 is turned on by the voltage of the negative polarity among the first scan signals GW transmitted through the first scan line 151, the data voltage DATA transmitted through the data line 171 is delivered to the first electrode of the drive transistor T1, and ultimately, the data voltage DATA is delivered to the gate electrode of the drive transistor T1 and stored in the storage capacitor Cst.

In an embodiment, the third transistor T3 is an n-type transistor, and its semiconductor layer consists of an oxide semiconductor also referred to as the second semiconductor.

In an embodiment, the third transistor T3 electrically connects the second electrode of the drive transistor T1 and the gate electrode of the drive transistor T1.

As a result, in an embodiment, T3 is a transistor that compensates the data voltage DATA by the threshold voltage of the drive transistor T1, and stores it in the second maintenance electrode of the storage capacitor Cst.

In an embodiment, the gate electrode of the third transistor T3 is connected to the second scan line 152, and the first electrode of the third transistor T3 is connected to the second electrode of the drive transistor T1.

In an embodiment, the second electrode of the third transistor T3 is connected to the second maintenance electrode of the storage capacitor Cst, the gate electrode of the drive transistor T1, and the other electrode hereinafter referred to as upper boost electrode of the boost capacitor C_{boost}.

In an embodiment, the third transistor T3 is turned on by the positive voltage of the second scan signal GC transmitted through the second scan line 152, connecting the gate electrode of the drive transistor T1 and the second electrode of the drive transistor T1, and transferring the voltage applied to the gate electrode of the drive transistor T1 to the second maintenance electrode of the storage capacitor Cst to store it in the storage capacitor Cst.

At this time, in an embodiment, the voltage stored in the storage capacitor Cst is the voltage of the gate electrode of the drive transistor T1 when the drive transistor T1 is turned off, this is stored in a state where the threshold voltage Vth value of the drive transistor T1 is compensated.

In an embodiment, the fourth transistor T4 is an n-type transistor, and its semiconductor layer consists of an oxide semiconductor.

In an embodiment, the fourth transistor T4 serves to initialize the gate electrode of the drive transistor T1 and the second maintenance electrode of the storage capacitor Cst.

In an embodiment, the gate electrode of the fourth transistor T4 is connected to the initialization control line 153, and the first electrode of the fourth transistor T4 is connected to the first initialization voltage line 127.

In an embodiment, the second electrode of the fourth transistor T4 is connected to the second electrode of the third transistor T3, the second holding electrode of the holding capacitor Cst, the gate electrode of the drive transistor T1, and the upper boost electrode of the boost capacitor C_{boost}.

In an embodiment, the fourth transistor T4 is turned on by the positive voltage of the initialization control signal GI received through the initialization control line 153, and at this time, T4 delivers the first initialization voltage VINT to the gate electrode of the drive transistor T1, the second maintenance electrode of the storage capacitor Cst, and the upper boost electrode of the boost capacitor C_{boost} for initialization.

In an embodiment, the fifth transistor T5 and the sixth transistor T6 are p-type transistors, and they each have a silicon semiconductor as the semiconductor layer.

In an embodiment, the fifth transistor T5 serves the function of delivering the drive voltage ELVDD to the drive transistor T1.

In an embodiment, the gate electrode of the fifth transistor T5 is connected to the light emitting control line 155, the first electrode of the fifth transistor T5 is connected to the driving voltage line 172, and the second electrode of the fifth transistor T5 is connected to the first electrode of the drive transistor T1.

In an embodiment, the sixth transistor T6 serves the role of transmitting the light emitting current output from the drive transistor T1 to the light emitting diode LED.

In an embodiment, the gate electrode of the sixth transistor T6 is connected to the light emitting control line 155, the first electrode of the sixth transistor T6 is connected to the second electrode of the drive transistor T1, and the second electrode of the sixth transistor T6 is connected to the anode of the light emitting diode LED.

In an embodiment, the seventh transistor T7 may be a p-type or n-type transistor, and the semiconductor layer may consist of silicon semiconductors or oxide semiconductors. In an embodiment, the seventh transistor T7 is a p-type transistor, which includes a silicon semiconductor.

In an embodiment, the seventh transistor T7 serves to initialize the anode of the light emitting diode LED.

In an embodiment, the gate electrode of the seventh transistor T7 is connected to the first scan line 151, the first electrode of the seventh transistor T7 is connected to the anode of the light emitting diode LED, and the second electrode of the seventh transistor T7 is connected to the second initialization voltage line 128.

In an embodiment, the gate electrode of the seventh transistor T7 is connected to the first scan line 151 of the transfer pixel, and it is not connected to the same first scan line 151 as the gate electrode of the second transistor T2 belonging to the same pixel PX, but it may be connected to the same first scan line 151 as the gate electrode of the second transistor T2 of the transfer pixel PX.

In an embodiment, when the seventh transistor T7 is turned on by the voltage of the first scan line 151, the second reset voltage VAINT is applied to the anode of the light emitting diode LED and is reset.

In an embodiment, the gate electrode of the seventh transistor T7 may also be controlled separately through a separate bypass control line connected to the bypass signal GB, and may be controlled by a separate wiring from the first scan line 151.

In addition, according to an embodiment, the second reset voltage line 128 to which the second reset voltage VAINT is applied may be the same as the first reset voltage line 127 to which the first reset voltage VINT is applied.

In an embodiment, one pixel PX includes seven transistors T1 to T7 and two capacitors, storage capacitor Cst and boost capacitor C_{boost}, but it is not limited to this, and depending on the embodiment, the boost capacitor C_{boost} may be excluded.

In addition, according to an embodiment, an additional boost capacitor may be formed between the gate electrode of the third transistor T3 and the gate electrode of the drive transistor T1.

In addition, in an embodiment, although the third transistor and the fourth transistor are formed as n-type transistors, one of them may be formed as an n-type transistor or other transistors, such as the seventh transistor, for example, may also be formed as n-type transistors.

As described above, in an embodiment, a pixel of a display device includes two types of semiconductors positioned on different layers, and the two types of semiconductors are a polycrystalline semiconductor (also referred to as a first semiconductor) and an oxide semiconductor (also referred to as a second semiconductor).

In an embodiment, each of these is included in a transistor, and hereinafter, a transistor including a polycrystalline semiconductor is referred to as a polycrystalline transistor, and a transistor including an oxide semiconductor is referred to as an oxide transistor.

In an embodiment, one pixel may include both a polycrystalline transistor and an oxide transistor, and the drive transistor T1 that provides driving current to the light emitting diode LED is formed as a polysilicon transistor.

In an embodiment, all of the transistors other than the drive transistor T1 are also referred to as switching transistors, and the switching transistors may be classified into polycrystalline switching transistors and oxide switching transistors.

Hereinafter, a stacked structure of the display area will be described with reference to FIG. 4, according to an embodiment.

In an embodiment, the display device may be largely divided into a lower panel layer and an upper panel layer, where the lower panel layer is a portion where light emitting diodes constituting pixels and pixel circuits are positioned, and may even include an encapsulation layer 400 covering them.

In an embodiment, t, the pixel circuitry includes a second organic layer 182 and a third organic layer 183, which refers to the underlying structure, and the light emitting diode is positioned on the upper part of the third organic layer 183, which may refer to the configuration positioned on the lower part of the encapsulation layer 400.

In an embodiment, the structure positioned on the upper part of the encapsulation layer 400 may correspond to the upper panel layer, and depending on the embodiment, it may include color filters or color conversion layers.

In addition, in an embodiment, the third organic layer 183 may not be included.

First, in an embodiment, a metal layer BML is positioned on the substrate 110.

In an embodiment, the substrate 110 may include a material that does not bend, such as glass, or a flexible material that may be bent, such as plastic or polyimide.

In an embodiment, in the case of a flexible substrate, a double-layer structure of polyimide and a barrier layer formed of an inorganic insulating material thereon may have a double structure.

In an embodiment, the metal layer BML may be formed at a position overlapping the channel and plane of the drive transistor in the subsequent first semiconductor layer ACT1, and it is also called the underlying shielding layer.

In an embodiment, the metal layer BML may include metals or metal alloys such as copper Cu, molybdenum Mo, aluminum Al, and titanium Ti.

Here, in an embodiment, the drive transistor may refer to a transistor that generates current transmitted to the light emitting diode.

In an embodiment, on top of the substrate 110 and the metal layer BML, there is a buffer layer 111 that covers them.

In an embodiment, the buffer layer 111 plays a role in blocking the infiltration of impurities into the first semiconductor layer ACT1, and may be an inorganic insulating layer containing silicon oxide SiOₓ, silicon nitride SiNₓ, or silicon oxynitride SiOₓN_{y}.

In an embodiment, on top of the buffer layer 111 is the first semiconductor layer ACT1 containing silicon semiconductors such as polycrystalline silicon P—Si.

In an embodiment, the first semiconductor layer ACT1 includes the channel of a polycrystalline transistor including a drive transistor, as well as the first region and second region positioned on both sides of it.

Here, in an embodiment, the polycrystalline transistor may include a plurality of polycrystalline switching transistors as well as a drive transistor.

In addition, in an embodiment, the first region and the second region corresponding to both sides of the channel of the first semiconductor layer ACT1 have regions having conductive layer characteristics by plasma treatment or doping, thereby serving as the first and second electrodes of the transistor.

In an embodiment, on top of the first semiconductor layer ACT1, the first gate insulation layer 141 may be positioned.

In an embodiment, the first gate insulation layer 141 may be an inorganic insulating layer containing silicon oxide SiOₓ, silicon nitride SiNₓ, or silicon oxynitride SiOₓN_{y}, etc.

In an embodiment, a first gate conductive layer containing a gate electrode GE1 of a polycrystalline transistor may be positioned on top of the first gate insulation layer 141.

In an embodiment, a scan line or an emission control line may be formed in the first gate conductive layer in addition to the gate electrode GE1 of the polycrystalline transistor.

In an embodiment, the first gate conductive layer formed of different materials may be divided into a 1-1 gate conductive layer and a 1-2 gate conductive layer.

In an embodiment, after forming the first gate conductive layer, an exposed region of the first semiconductor layer may be made conductive by performing a plasma treatment or a doping process.

That is, in an embodiment, the first semiconductor layer ACT1 covered by the first gate conductive layer is not conductive, and the portion of the first semiconductor layer ACT1 not covered by the first gate conductive layer has the same characteristics as the conductive layer.

In an embodiment, on top of the first gate conductive layer and the first gate insulation layer 141, the second gate insulation layer 142 may be positioned.

In an embodiment, the second gate insulation layer 142 may be an inorganic insulating layer containing silicon oxide SiOₓ, silicon nitride SiNₓ, or silicon oxynitride SiOₓN_{y}.

In an embodiment, the second gate insulating layer 142 may be positioned on top of the storage capacitor Cst with a first electrode CE positioned on the second gate insulating layer.

In an embodiment, the floating electrode CE of the storage capacitor Cst forms the storage capacitor Cₛₜ by overlapping the gate electrode GE1 of the drive transistor.

According to embodiments, the second gate conductive layer may further include a lower shielding layer BML-1 of the oxide transistor.

In an embodiment, the lower shielding layer BML-1 of the oxide transistor may be positioned below the channel of each oxide transistor, and it may play a role in shielding from light or electromagnetic interference provided to the channel from the bottom.

According to embodiments, the second gate conductive layer may further include a scan line, a control line, and/or a voltage line.

In an embodiment, the second gate conductive layer may include metals or metal alloys such as copper Cu, molybdenum Mo, aluminum Al, or titanium Ti, and may be composed of a single layer or multiple layers.

In an embodiment, on top of the second gate conductive layer, a first interlayer insulation layer 161 may be positioned.

In an embodiment, the first interlayer insulation layer 161 may include inorganic insulation layers containing silicon oxide SiOₓ, silicon nitride SiNₓ, silicon oxynitride SiOₓN_{y}, etc., and according to an embodiment, it is possible to form thick inorganic insulation materials.

In an embodiment, on top of the first interlayer insulation layer 161, there may be a second semiconductor layer oxide semiconductor layer, ACT2 containing oxide semiconductors.

In an embodiment, oxide semiconductors may include at least one of monovalent metal oxides such as indium oxide In, tin oxide Sn, or zinc oxide Zn, bivalent metal oxides such as In—Zn oxide, Sn—Zn oxide, Al—Zn oxide, Zn—Mg oxide, Sn—Mg oxide, In—Mg oxide, or In—Ga oxide, trivalent metal oxides such as In—Ga—Zn oxide, In—Al—Zn oxide, In—Sn—Zn oxide, Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn oxide, In—Tb—Zn oxide, In—Dy—Zn oxide, In—Ho—Zn oxide, In—Er—Zn oxide, In—Tm—Zn oxide, In—Yb—Zn oxide, or In—Lu—Zn oxide, and tetravalent metal oxides such as In—Sn—Ga—Zn oxide, In—Hf—Ga—Zn oxide, In—Al—Ga—Zn oxide, In—Sn—Al—Zn oxide, In—Sn—Hf—Zn oxide, or In—Hf—Al—Zn oxide.

For example, in an embodiment, the second semiconductor layer ACT2 may include IGZO indium-gallium-zinc oxide among the In—Ga—Zn oxide compounds.

In an embodiment, the second semiconductor layer ACT2 may include at least one of indium-gallium-zinc oxide IGZO, indium-zinc-tin oxide IZTO, indium-gallium-zinc-tin oxide IGZTO, and indium-gallium oxide IGO.

In an embodiment, on top of the second semiconductor layer ACT2, a third gate insulation layer 143 may be positioned.

In an embodiment, the third gate insulation layer 143 may be positioned on the front of the second semiconductor layer ACT2 and the first interlayer insulation layer 161.

In an embodiment, the third gate insulation layer 143 may include an inorganic insulating layer containing silicon oxide SiOₓ, silicon nitride SiNₓ, or silicon oxynitride SiOₓN_{y}.

In an embodiment, on top of the third gate insulation layer 143, there may be a third gate electrode layer including the gate electrode GE3 of the oxide transistor.

In an embodiment, the gate electrode GE3 of an oxide transistor may overlap the channel.

In an embodiment, the third gate conductive layer may include additional scan lines or control lines.

In an embodiment, the third gate challenging layer may include metals or metal alloys such as copper Cu, molybdenum Mo, aluminum Al, and titanium Ti, and may be composed of a single layer or multiple layers.

In an embodiment, a second interlayer insulation layer 162 may be positioned on the third gate conductive layer.

In an embodiment, the second interlayer insulation layer 162 may have a single layer or multiple layers.

The second interlayer insulation layer 162 may include an inorganic insulating material such as silicon nitride SiNₓ, silicon oxide SiOₓ, and silicon nitride oxide SiOₓN_{y}, and may include an organic material, according to embodiments.

In an embodiment, a first data conductive layer including connecting members C1, C2, C3, C4 capable of being connected to the first and second regions of the polycrystalline transistor and the oxide transistor, respectively, may be positioned on the second interlayer insulation layer 162.

In an embodiment, the first data conductive layer may include a metal or metal alloy such as aluminum Al, copper Cu, molybdenum Mo, or titanium Ti, and may be composed of a single layer or multiple layers.

In an embodiment, a first organic layer 181 may be positioned on the first data conductive layer.

In an embodiment, the first organic layer 181 may be an organic insulating layer including an organic material, and the organic material may include at least one material selected from the group consisting of polyimide, polyamide, acrylic resin, benzocyclobutene, and phenol resin.

In an embodiment, on top of the first organic layer 181, a second data conductive layer containing an anode connection member ACM2 may be positioned.

In an embodiment, the second data conductive layer may include a data line or a driving voltage line.

In an embodiment, the second data conductive layer may include metals or metal alloys such as aluminum Al, copper Cu, molybdenum Mo, and titanium Ti, and may be composed of a single layer or multiple layers.

In an embodiment, the anode connection member ACM2 is connected to the first data conductive layer through an opening OP3 positioned on the first organic layer 181.

In an embodiment, above the second data conductive layer, there are the second organic layer 182 and the third organic layer 183, and the second organic layer 182 and the third organic layer 183 have openings OP4 formed for anode connection.

In an embodiment, the anode connection member ACM2 is electrically connected to the anode through the anode connection openings OP4.

In an embodiment, the second organic layer 182 and the third organic layer 183 may be organic insulating layers, and may include one or more substances selected from a group consisting of polyimide, polyamide, acrylic resin, benzocyclobutene, and phenolic resin.

According to an embodiment, the third organic layer 183 may be omitted.

In an embodiment, on top of the anode, there may be a pixel defining layer 380 that has an opening OP exposing the anode while covering at least a portion of the anode.

The pixel defining layer 380 may be a black pixel defining layer formed of a black organic material to prevent externally applied light from being reflected back to the outside, or may be formed of a transparent organic material according to embodiments.

Above the pixel defining layer 380, a spacer 385 is positioned, according to an embodiment.

In an embodiment, the spacer 385 may be formed from transparent organic insulating materials.

According to an embodiment, the spacer 385 may be formed of a positive-type transparent organic material.

In an embodiment, the spacer 385 may include two different parts having different heights 385-1, 385-2, with the higher part 385-1 performing the role of the spacer, and the lower part 385-2 being able to improve the adhesive characteristics between the spacer and the pixel defining layer 380.

In an embodiment, on top of the anode, the spacer 385, and the pixel defining layer 380, a functional layer FL and the cathode are sequentially formed, and the functional layer FL and the cathode may be positioned throughout the entire area.

In an embodiment, between the functional layers FL, there is a light emitting layer EML, and the light emitting layer EML may only be positioned within the opening OP of the pixel defining layer 380.

In the following, the combination of the functional layer FL and the light emitting layer EML may be referred to as the intermediate layer, according to an embodiment.

In an embodiment, the functional layer FL may include at least one of an electron injection layer, an electron transport layer, a hole transport layer, and an auxiliary layer such as a hole injection layer, and the hole injection layer and the hole transport layer are disposed under the light emitting layer EML and an electron transport layer and an electron injection layer may be positioned on the light emitting layer EML.

In an embodiment, on top of the cathode, there is an encapsulation layer 400.

In an embodiment, the encapsulation layer 400 includes at least one inorganic layer and at least one organic layer, and may have a triple layer structure including a first inorganic encapsulation layer, an organic encapsulation layer, and a second inorganic encapsulation layer.

In an embodiment, the encapsulation layer 400 may be used to protect the light emitting layer EML from moisture or oxygen that may be introduced from the outside.

According to an embodiment, the encapsulation layer 400 may include a structure where the inorganic layer and the organic layer are sequentially stacked.

In an embodiment, on top of the encapsulation layer 400, there are detection insulation layers 501, 510, 511 and a plurality of sensing electrodes 540, 541 for touch detection.

In an embodiment, using two sensing electrodes 540, 541, touch may be detected in a capacitive type.

Specifically, in an embodiment, above the encapsulation layer 400, a first detection insulation layer 501 is formed, and a plurality of sensing electrodes 540, 541 are formed on top of it.

In an embodiment, a plurality of sensing electrodes 540, 541 may be insulated between the second detection insulation layer 510 and some of them may be electrically connected through openings positioned in the detection insulation layer 510.

In an embodiment, the sensing electrodes 540, 541 may include metals or metal alloys such as aluminum Al, copper Cu, silver Ag, gold Au, molybdenum Mo, titanium Ti, and tantalum Ta, and may be composed of a single layer or a plurality of layers.

In an embodiment, on top of the sensing electrode 540, a third detection insulation layer 511 is formed.

In an embodiment, although no configuration is shown on the third detection insulation layer 511, a layer including a polarizing plate may be attached to reduce reflection of external light, or a color filter or color conversion layer may be further formed to improve color quality.

In an embodiment, a light blocking member may be positioned between the color filters or the color conversion layer.

In addition, in an embodiment, a layer including a material capable of absorbing some wavelengths of external light hereinafter referred to as a reflection adjusting material may be further included.

In addition, in an embodiment, the front surface of the light emitting display device may be flattened by covering it with an additional organic layer also referred to as a planarization layer.

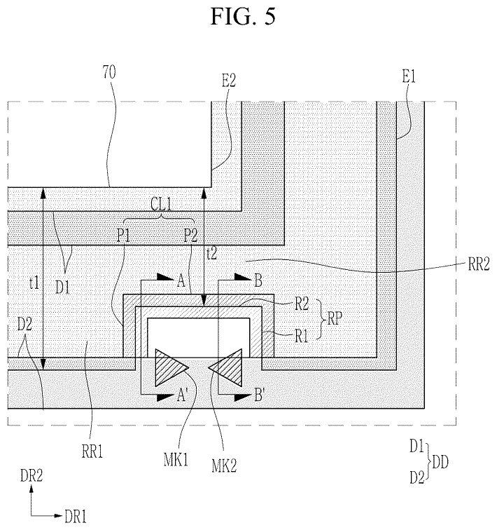

Hereinafter, region A of FIG. 2 will be described with reference to FIG. 5 to FIG. 7.

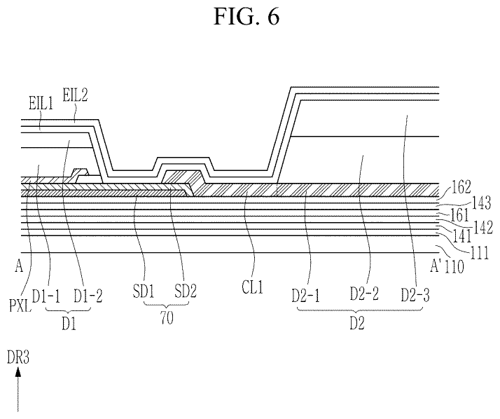

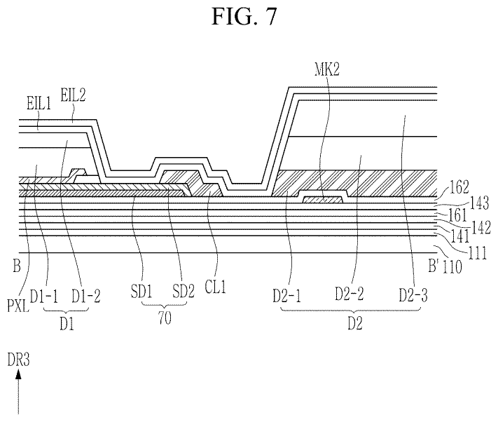

According to embodiments, FIG. 5 is an enlarged top plan view of region A of FIG. 2, FIG. 6 is a cross-sectional view taken along line A-A′ of FIG. 5, and FIG. 7 is a cross-sectional view taken along line B-B′ of FIG. 5.

In an embodiment, a dam unit DD may be disposed in the non-display area PA.

The dam unit DD may include at least two dams D1, D2.

FIG. 5 shows an embodiment of a structure in which two dams D1, D2 are disposed, but the invention is not limited thereto.

In an embodiment, when forming the organic encapsulation layer EOL of the encapsulation layer 400 in FIG. 4, a dam unit DD may prevent the overflow of the organic encapsulation layer EOL by blocking the flow of organic material towards the edge of the substrate 110.

In an embodiment, the dam unit DD may be disposed to at least partially surround the display area DA on the non-display area PA.

In an embodiment, the first dam D1 and the second dam D2 may be provided separately from each other, and the first dam D1 may be arranged to surround at least a part of the second dam D2.

In an embodiment, the first dam D1 and the second dam D2 may have a single layer or multiple layers.

In an embodiment and referring to the FIG. 6, the first dam D1 includes the first-1 dam D1-1 and the first-2 dam D1-2, and the second dam D2 may include the second-1 dam D2-1, the second-2 dam D2-2, and the second-3 dam D2-3.

This disclosure describes an embodiment in which the first dam D1 and the second dam D2 have different heights, but it is not limited to this.

In an embodiment, the first dam D1 and the second dam D2 may include the same materials as the organic layers positioned in the display area DA, and may be formed in the same process.

According to an embodiment, the non-display area PA may include a cover organic layer CL1 connected to the second dam D2.

In an embodiment, the cover organic layer CL1 may have a protruding shape from the second dam D2 towards the first dam D1.

In an embodiment, the cover organic layer CL1 may be separated from the first dam D1.

In an embodiment, the cover organic layer CL1 may block the pathway of moisture flowing from the second dam D2 to the first dam D1 by not being connected to the first dam D1.

In an embodiment, the cover organic layer CL1 may include the same material as the second organic layer 182 described in FIG. 4 and may be formed in the same process as the second organic layer 182.

Alternatively, a cover organic layer CL1, according to another embodiment, may include the same material as the third organic layer 183 described in FIG. 4 and may be formed in the same process as the third organic layer 183.

In an embodiment, the cover organic layer CL1 may overlap a portion of a common voltage transmission line 70.

In an embodiment, the cover organic layer CL1 may overlap a portion of the edge of the common voltage transmission line 70.

In an embodiment, the common voltage transmission line 70 may include a first edge E1 located adjacent to the first dam D1 and a second edge E2 located adjacent to the second dam D2.

In an embodiment, the shape of the common voltage transmission line 70 may be determined by the first edge E1 and the second edge E2.

In an embodiment, the second edge E2 of the common voltage transmission line 70 may include a protruding portion RP directed towards the first dam D1.

In an embodiment, the protruding portion RP may be positioned between the first dam D1 and the second dam D2.

According to an embodiment, the protruding portion RP may include two first portions R1 protruding from the second edge E2 in the extension direction, and a second portion R2 connecting the aforementioned two first portions R1.

For example, in an embodiment, he second edge E2 may be extended along the first direction DR1, and may include a protruding portion RP in the second direction DR2.

In an embodiment, the protruding portion RP includes two first parts R1 protruding in the second direction DR2, and may include a second part R2 that connects the two first parts R1 and that extends in the first direction DR1.

However, it is not limited to these embodiments, and depending on other embodiments, the second edge E2 extending along the second direction DR2 may also include protrusions in the first direction DR1.

In an embodiment, the protruding portion may include two first parts R1 protruding in the first direction DR1, and may include a second part R2 that extends in the second direction DR2 connecting the two first parts R1.

According to an embodiment, the cover organic layer CL1 may cover the protruding portion towards the first dam D1 from the second edge E2.

In an embodiment, the cover organic layer CL1 may overlap the first part R1 and the second part R2 of the protruding portion RP.

In an embodiment, the cover organic layer CL1 may include a first region P1 covering the first part R1 and a second region P2 covering the second part R2.

In an embodiment, the first region P1 is connected to the second dam D2 and may be extended from the second dam D2.

In an embodiment, the second region P2 may connect two adjacent first regions P1 to each other.

According to an embodiment, the common voltage transmission line 70 may include a first region RR1 having a first width t1 and a second region RR2 having a second width t2.

In an embodiment, the first width t1 may be larger than the second width t2.

In an embodiment, the common voltage transmission line 70 may have a depression shape in the second region RR2 on a plan view.

In an embodiment, the common voltage transmission line 70 may include a depression in a plan view.

In an embodiment, the common voltage transmission line 70 may overlap at least part of the first dam D1 and the second dam D2 in the first region RR1.

Furthermore, in an embodiment, the common voltage transmission line 70 may overlap with the first dam D1 in the second region RR2 and may be spaced apart from the second dam D2.

In an embodiment, the second region RR2 may overlap the first dam D1 and cover the organic layer CL1.

In an embodiment, the alignment key MK1, MK2 may overlap at least part of the second dam D2.

In addition, in an embodiment, the alignment key MK1, MK2 may be positioned in the depression of the common voltage transmission line 70 in a plan view.

In an embodiment, the alignment keys MK1, MK2 may be arranged to have a predetermined distance from the common voltage transmission line 70.

In an embodiment, the alignment key MK1, MK2 may be used to check the alignment status and other necessary conditions during the manufacturing process.

In an embodiment, the alignment key MK1, MK2 may be made of opaque materials, as it needs to be visible from the outside.

In addition, in an embodiment, the alignment key MK1, MK2 may be configured as island patterns spaced apart from other conductive patterns on a plane to improve visibility.

Hereinafter, the cross-sectional structure of FIG. 5 will again be described in more detail with reference to FIG. 6 and FIG. 7.

According to an embodiment, a buffer layer 111 extending from the display area DA, a first gate insulation layer 141, a second gate insulation layer 142, a first interlayer insulation layer 161, a third gate insulation layer 143, and a second interlayer insulation layer 162 may be positioned on the substrate 110 of the non-display area PA.

In an embodiment, at least one of the buffer layer 111, the first gate insulation layer 141, the second gate insulation layer 142, the first interlayer insulation layer 161, the third gate insulation layer 143, and the second interlayer insulation layer 162 may be partially removed.

In an embodiment and as shown in FIG. 7, the second interlayer insulation layer 162 may be positioned on the alignment key MK1, MK2.

In an embodiment, the align keys MK1 and MK2 include the same material as the third gate conductive layer including the gate electrode GE3 of the oxide transistor disposed in the display area DA, and may be formed in the same process.

In an embodiment, the alignment key MK1, MK2 may overlap at least some parts of the second dam D2.

In an embodiment, the alignment key MK1, MK2 may reduce the area occupied by the non-display area PA in the display device by overlapping at least a portion of the second dam D2.

In an embodiment, a common voltage transmission line 70 may be positioned on the second interlayer insulation layer 162.

In an embodiment, the common voltage transmission line 70 may include at least one of the first layer SD1 formed in the same process as the first data conductive including the connecting members C1, C2, C3, C4 of the display area DA, and the second layer SD2 formed in the same process as the second data conductive layer including the anode connecting member ACM2.

According to an embodiment, the common voltage transmission line 70 may include a third layer PXL formed in the same process as the anode.

In an embodiment, the first dam D1 may be positioned on the common voltage transmission line 70.

In an embodiment, the first dam D1 may include first-1 dam D1-1 and first-2 dam D1-2.

In an embodiment, the first-1 dam D1-1 includes the same material as the pixel defining layer 380 located in the display area DA, and may be formed in the same process.

In an embodiment, the first-2 dam D1-2 includes the same material as the spacer 385 located in the display area DA and may be formed in the same process.

In an embodiment, the second dam D2 may be positioned on another part of the common voltage transmission line 70.

In an embodiment, the second dam D2 may also include some areas that do not overlap the common voltage transmission line 70.

FIG. 6 and FIG. 7 represent regions where the common voltage transmission line 70 is not positioned on the second dam D2, according to embodiments.

In an embodiment, the second dam D2 may include the second-1 dam D2-1, the second-2 dam D2-2, and the second-3 dam D2-3.

In an embodiment, the second-1 dam D2-1 includes the same material as the second organic layer 182 positioned in the display area DA, and may be formed in the same process as the second organic layer 182.

Alternatively, the second-1 dam D2-1, according to another embodiment, may include the same material as the third organic layer 183, and may be formed in the same process as the third organic layer 183.

In an embodiment, the second-2 dam D2-2 may include a pixel defining layer 380 made of the same material as the display area DA, and may be formed in the same process.

In an embodiment, the second-3 dam D2-3 includes the same material as the spacer 385 located in the display area DA and may be formed in the same process.

The cover organic layer CL1 may include the same material as the second organic layer 182 positioned in the display area DA, according to an embodiment, and may be formed in the same process as the second organic layer 182.

Alternatively, in an embodiment, the cover organic layer CL1 may include the same material as the third organic layer 183, and may be formed in the same process as the third organic layer 183.

In an embodiment, the cover organic layer CL1 and the second dam D2 may be connected to each other.

In particular, according to an embodiment, the cover organic layer CL1 may be connected to the second-1 dam D2-1.

In an embodiment, the cover organic layer CL1 and the second-1 dam D2-1 may be formed in the same process, and may be formed as a whole.

In an embodiment, the cover organic layer CL1 may cover the end of the common voltage transmission line 70.

In an embodiment, the cover organic layer CL1 may particularly cover a portion of the second edge E2 of the common voltage transmission line 70.

In an embodiment, the cover organic layer CL1 may cover the protruding portion RP which protrudes towards the first edge E1 among the second edges E2.

In an embodiment and referring to FIG. 6 and FIG. 7, the common voltage transmission line 70 may include portions uncovered by the first dam D1, the cover organic layer CL1, and the second dam D2.

In an embodiment, a part of the upper surface of the common voltage transmission line 70 may not be covered by the organic layer.

In an embodiment, the upper surface of the common voltage transmission line 70 may be covered by a first encapsulation inorganic layer EIL1.

In addition, in an embodiment, the cover organic layer CL1 and the second dam D2 may include separated regions.

In an embodiment, in the separated regions between the second dam and the cover organic layer CL1, the upper surface of the second interlayer insulation layer 162 may be exposed.

In an embodiment, the upper surface of the second interlayer insulation layer 162, which is not covered by other elements may be covered by the first encapsulation inorganic layer EIL1, which may block the permeation path.

In an embodiment, there is a possibility that natural oxidation may occur in the area adjacent to the second dam D2 in high-temperature and high-humidity environments as the area occupied by the non-display area PA decreases.

According to an embodiment, the first dam D1 and the second dam D2 are spaced apart from each other, and the cover organic layer CL1 covering the end of the common voltage transmission line 70 may be spaced apart from the first dam D1.

In an embodiment, the moisture that flows in through the second dam D2 may move to the cover organic layer CL1, but it cannot move to the first dam D1.

Therefore, the cover organic layer CL1, according to an embodiment, may protect the wiring by covering the edge of the common voltage transmission line 70 and may be spaced apart from the first dam D1, thus blocking the path for movement of moisture.

In an embodiment, it may be possible to provide a display device having an excellent moisture permeation prevention effect.

In an embodiment, since the common voltage transmission line provides an area where an alignment key is disposed and has a wiring width of a certain level or more, IR drop may be reduced.

Although embodiments of the invention have been described in detail above, the scope of the invention is not limited thereto, and various modifications and improvements may be made by a person of an ordinary skill in the art using the basic concepts of the invention. Embodiments of the invention disclosed in the disclosure and illustrated in the drawings are provided as particular examples for more easily explaining the technical contents according to the invention and helping understand the embodiments of the invention, but they not intended to limit the scope of the embodiments of the invention. Accordingly, the scope of the invention should be interpreted to include, in addition to the embodiments disclosed herein, all alterations or modifications derived from the technical ideas of the various embodiments. Moreover, the embodiments or parts of the embodiments may be combined in whole or in part without departing from the scope of the invention.

What is claimed is:

1. A display device, comprising:
a substrate including a display area and a non-display area;
a transistor positioned in the display area;
a light emitting element electrically connected to the transistor;
a common voltage transmission line positioned in the non-display area and including a depression;
a first dam and a second dam positioned in the non-display area and spaced apart from each other while surrounding at least a portion of the display area;
a cover organic layer overlapping an edge of the depression; and
an edge of the depression positioned between the first dam and the second dam.

2. The display device of claim 1, wherein,
the common voltage transmission line includes,
a first region having a first width; and
a second region having a second width, wherein the first width is greater than the second width.

3. The display device of claim 2, wherein,
the second region has a recessed portion compared to the first region.

4. The display device of claim 1, wherein,
the common voltage transmission line includes a first edge and a second edge, wherein the first edge is positioned adjacent to the first dam,
the second edge is positioned adjacent to the second dam, and
at least a portion of the second edge overlaps the second dam.

5. The display device of claim 4, wherein,
the second edge includes a protruding portion extending toward the first edge, and
overlapping the cover organic layer.

6. The display device of claim 1, wherein:
the display area comprises:
a first semiconductor layer positioned on the substrate;
a first gate conductive layer positioned on the first semiconductor layer;
a second gate conductive layer positioned on the first gate conductive layer;
a second semiconductor layer positioned on the second gate conductive layer;
a third gate conductive layer positioned on the second semiconductor layer;
a first data conductive layer positioned on the third gate conductive layer;
a second data conductive layer positioned on the first data conductive layer; and
a first electrode positioned on the second data conductive layer.

7. The display device of claim 6, wherein:
the common voltage transmission line comprises
at least one of a first layer positioned on a same layer as the first data conductive layer, and
a second layer positioned on a same layer as the second data conductive layer.

8. The display device of claim 6, further comprising:
a recessed portion on the second region and an alignment key overlapping at least a portion of the recessed portion on a plan view.

9. The display device of claim 8, wherein:
the alignment key is positioned on a same layer as the third gate conductive layer.

10. The display device of claim 6, wherein:
the display device comprises:
a first gate insulation layer positioned on the first semiconductor layer;
a second gate insulation layer positioned on the first gate conductive layer;
a first interlayer insulation layer positioned on the second gate conductive layer;
a third gate insulation layer positioned on the second semiconductor layer;
a second interlayer insulation layer positioned on the third gate conductive layer;
a first organic layer on the first data conductive layer;
a second organic layer and a third organic layer disposed on the second data conductive layer; and
a pixel defining layer and a spacer disposed on the first electrode.

11. The display device of claim 10, wherein:
the cover organic layer includes a material identical to at least one of the second organic layer and the third organic layer.

12. The display device of claim 11, wherein:
the cover organic layer is connected to the second dam.

13. The display device of claim 1, wherein:
the first dam and the cover organic layer are spaced apart from each other.

14. The display device of claim 1, wherein:
the cover organic layer has a protruding shape extending toward the first dam in a plan view.

15. A display device, comprising:
a substrate including a display area and a non-display area;
a transistor positioned in the display area;
a light emitting element electrically connected to the transistor;
a common voltage transmission line positioned in the non-display area;
a first dam and a second dam positioned in the non-display area, surrounding at least a portion of the display area, and spaced apart from each other; and
a cover organic layer protruding from a part of the second dam and spaced apart from the first dam, wherein the cover organic layer covers at least a portion of an edge of the common voltage transmission line.

16. The display device of claim 15, wherein:
the common voltage transmission line comprises:
a first edge located adjacent to the first dam; and
a second edge located adjacent to the second dam,
wherein the second edge includes a protruding portion extending towards the first dam.

17. The display device of claim 16, wherein:
the cover organic layer covers the protruding portion.

18. The display device of claim 17, wherein:
at least a portion of the second edge overlaps the second dam.

19. The display device of claim 15, wherein:
the common voltage transmission line includes a first area having a first width and a second area having a second width, wherein
the first width is greater than the second width.

20. The display device of claim 15, further comprising:
an alignment key overlapping at least a portion of the second dam.
